(19) United States
(12) Patent Application Publication
(10) Pub. No.: US 2005/0017159 A1
(43) Pub. Date: Jan. 27, 2005

(54) Electronic apparatus having movable readable member

(76) Inventors: Haruhiko Hasegawa, Chiba-shi (JP); Akihiro Iino, Chiba-shi (JP); Makoto Suzuki, Chiba-shi (JP)

Correspondence Address: Bruce L. Adams;Adams & Wilks, 31st Floor, 50 Broadway, New York, NY, 10004, US

(21) Appl. No.: 10/909,823

(22) Filed: Aug. 2, 2004

Related U.S. Application Data
(62) Division of application No. 09/988,870, filed on Nov. 19, 2001.

(30) Foreign Application Priority Data
Nov. 20, 2000 (JP) 2000-352777

(51) Int. Cl. H01L 41/08

(52) U.S. Cl. 250/231.13; 310/317; 310/323.01

(57) ABSTRACT

An electronic apparatus has a motor and a disc-shaped readable member rotationally driven by the motor and having at least one first slit therein and an optical amount adjusting slit having an arcuate shape with a radius of curvature identical to that of a rotational path of the readable member. A detecting device detects rotation of the readable member and has a light emitting element and a light receiving element sandwiching therebetween the readable member so that light is projected through the at least one first slit once for each revolution of the readable member.

### BACKGROUND OF THE INVENTION

1. Field of the Invention

The present invention relates to an electronic apparatus for detecting a position of a movable object member of, for example, an indicator, a mirror or the like.

2. Description of the Related Art

In recent years, in electronic apparatus, positioning control of a movable object member is an important technology and higher positioning accuracy is requested. As a method of carrying out positioning control of a movable object member, there is generally adopted a method of detecting position information of a moving member moved by drive force of an actuator and controlling movement of the moving member by feedback control based on the position information to thereby position the movable object member moving in cooperation with the moving member.

Further, in detecting a position of a moving member, for example, there are used an optical type encoder of an absolute type and an encoder of an incremental type. According to the optical type encoder of the absolute type, absolute position information is provided by a rotational position. Meanwhile, as shown by FIG. 2, the encoder of the incremental type is provided with a member to be read 2 having two rows of slits 2a at equal intervals for detecting a change in a rotational amount and having a slit 2b constituting a reference position for detecting absolute position information. Two signal shaving phases which differ by 90 degree are provided by way of the slits 2a and therefore, a single signal multiplied by four is provided therefrom to thereby achieve a resolution multiplied by four.

FIG. 3 shows an example of a structure for providing a rotational output by using an encoder of an incremental type. The structure is constituted by an actuator 16 which is a DC motor, a rotating shaft 100 for transmitting the rotational output of the actuator 16, detecting means having a pair of a light emitting element 8a and a light receiving element 8b, a member to be read 2 only the center of which is fixed to one side of the rotating shaft 100 by screwing or striking and an indicator 27 fixed to other side of the rotating shaft 100 by screwing or striking and operating as a movable object member. An absolute position of the indicator 27 is controlled based on a reference signal of the slit 2b constituting a reference of the member to be read 2.

However, according to the conventional electronic apparatus having position detecting apparatus, when the member to be read and the movable object member are attached to the rotating shaft, the rotating shaft is fixed to a hole portion of the member to be read by screwing or striking. Accordingly, there poses a problem that although positions of attaching the both members are determined in a radius direction, by the rotating shaft as a guide, a positional relationship of the slit constituting the reference of the member to be read and the movable object member is shifted in a peripheral direction. When the positional relationship is shifted, it is difficult to detect the absolute position information of the movable object member, as a result, regardless of the fact that the moving member is accurately positioned based on-the information of the member to be read, the movable object member is positioned to a position different from a desired position. An amount of the shift of the positional relationship between the slit constituting the reference of the member to be read and the movable object member, is dispersed also among products.

In order to eliminate the shift of the positional relationship between the slit constituting the reference of the member to be read and the movable object member in the peripheral direction, the positional relationship between the slit constituting the reference of the member to be read and the movable object member must be adjusted. The adjustment is carried out by taking time by a skilled worker and therefore, it is difficult to adjust the positional relationship simply. Therefore, a number of steps of adjusting and the like is increased and fabrication cost is also increased. Therefore, the method is not a method suitable for mass production.

### SUMMARY OF THE INVENTION

Hence, it is an object of the invention to eliminate a deviation in a positional relationship in a peripheral direction between a slit constituting a reference of a member to be read and a movable object member when the member to be read and the movable object member are attached to a moving member of, for example, a rotating shaft or the like, dispense with adjustment of the shift in the positional relationship therebetween, promote mass production performance and promote positional accuracy of the movable object member.

In order to resolve the above-described problem, according to an aspect of the invention, there is provided an electronic apparatus having a position detecting apparatus, the electronic apparatus comprising a movable object member having various functions, an actuator having a moving member moved to drive the movable object member, a member to be read for providing information with regard to a state of moving the movable object member, and a guide member for fixing the movable object member, the actuator and the member to be read. The aspect of the invention is characterized in that the member to be read and the movable object member are attached by the same guide member, or the member to be read and the movable object member are integrally formed such that a positional relationship between a slit constituting a reference of the member to be read and the movable object member is not shifted.

By fixing the movable object member and the member to be read by the guide member, the shift in the positional relationship between the slit constituting the reference of the member to be read and the movable object member is eliminated, further, adjustment of positions of attaching the both members is dispensed with, mass production performance is promoted and the dispersion in the positional relationship between the slit constituting the reference of the member to be read and the movable object member can be reduced.

### BRIEF DESCRIPTION OF THE DRAWINGS

FIG. 1 is an outline sectional view for explaining a constitution of an electronic apparatus according to Embodiment 1 of the invention;

FIG. 2 is an outline top view for explaining a member to be read according to a conventional example;

FIG. 3 is an outline sectional view for explaining a constitution of an electronic apparatus having a moving member, a member to be read and a movable object member according to a conventional example;

FIG. 4 is a block diagram for explaining a constitution of an electronic apparatus according to the invention;

FIG. 5 is an outline top view for explaining a member to be read of the electronic apparatus according to Embodiment 1 of the invention;

FIG. 6 is an outline sectional view for explaining a constitution of an electronic apparatus according to Embodiment 2 of the invention;

FIG. 7 is an outline top view for explaining a constitution of an electronic apparatus according to Embodiment 3 of the invention;

FIG. 8 illustrates an outline top view and an outline sectional view for explaining a constitution of an electronic apparatus according to Embodiment 4 of the invention;

FIG. 9 illustrates an outline top view and an outline sectional view for explaining a constitution of an electronic apparatus according to Embodiment 5 of the invention;

FIG. 10 is an outline top view for explaining a constitution of an electronic apparatus according to Embodiment 6 of the invention;

FIG. 11 is an outline sectional view for explaining a constitution of an electronic apparatus according to Embodiment 7 of the invention; and

FIG. 12 is an outline top view for explaining the constitution of the electronic apparatus according to Embodiment 7 of the invention.

### DETAILED DESCRIPTION OF THE PREFERRED EMBODIMENTS

A detailed explanation will be given of embodiments to which the invention is applied as follows.

### Embodiment 1

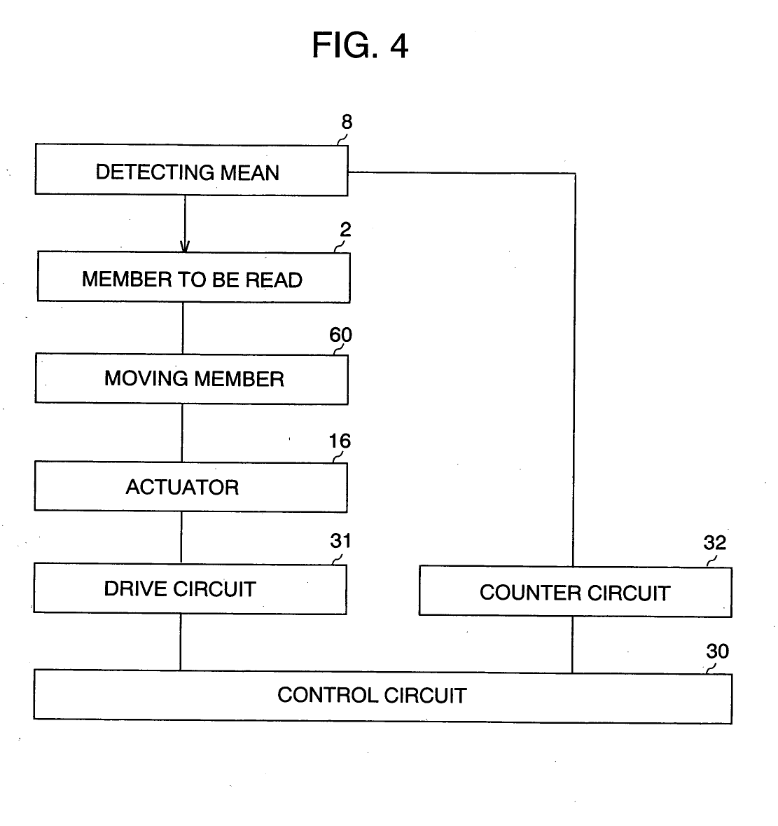

FIG. 4 shows a block diagram of an electronic apparatus according to the invention. A control circuit 30 outputs a control signal for instructing start, stop, regular rotation or reverse rotation of an actuator 16 to a drive circuit 31. The drive circuit 31 receives the control signal and inputs a drive signal based on the control signal to the actuator 16. The actuator 16 is driven by the drive signal and provides a moving member 60 with movement such as rotation or reciprocal movement. A member to be read 2 is similarly rotated or reciprocally moved in cooperation with the movement of the moving member 60. Detecting means 8 detects the rotation or the reciprocal movement of the member to be read 2. Further, the detecting means 8 is provided with a light emitting element and a light receiving element such as phototransistors. The detecting means 8 outputs a detected signal based on a state of the rotation or the reciprocal movement of the member to be read 2 by receiving information emitted from the light emitting element by the light receiving element. A counter circuit 32 calculates a moving amount based on the detected signal detected by the detecting means 8 and outputs the moving amount to the control circuit 30. The control circuit 30 compares the detected signal with a designated moving amount and outputs the control signal such that the moving member 60 gets proximate to the desired position.

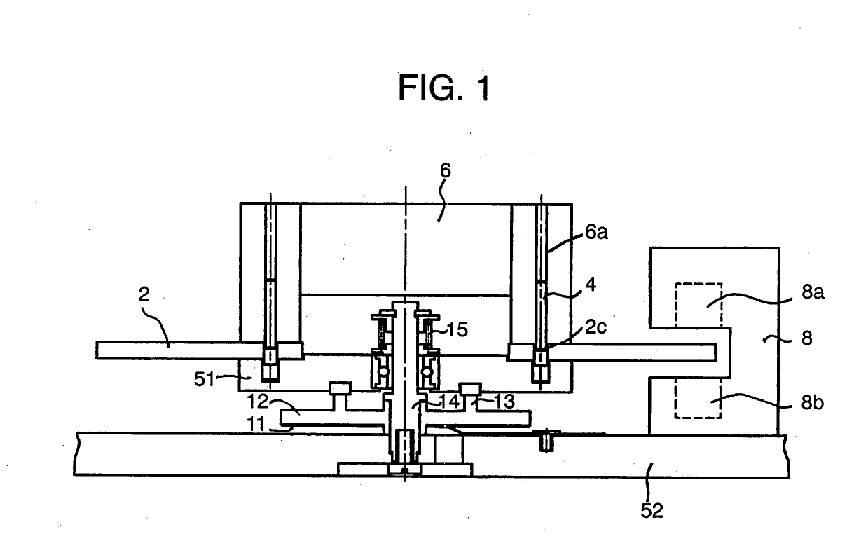

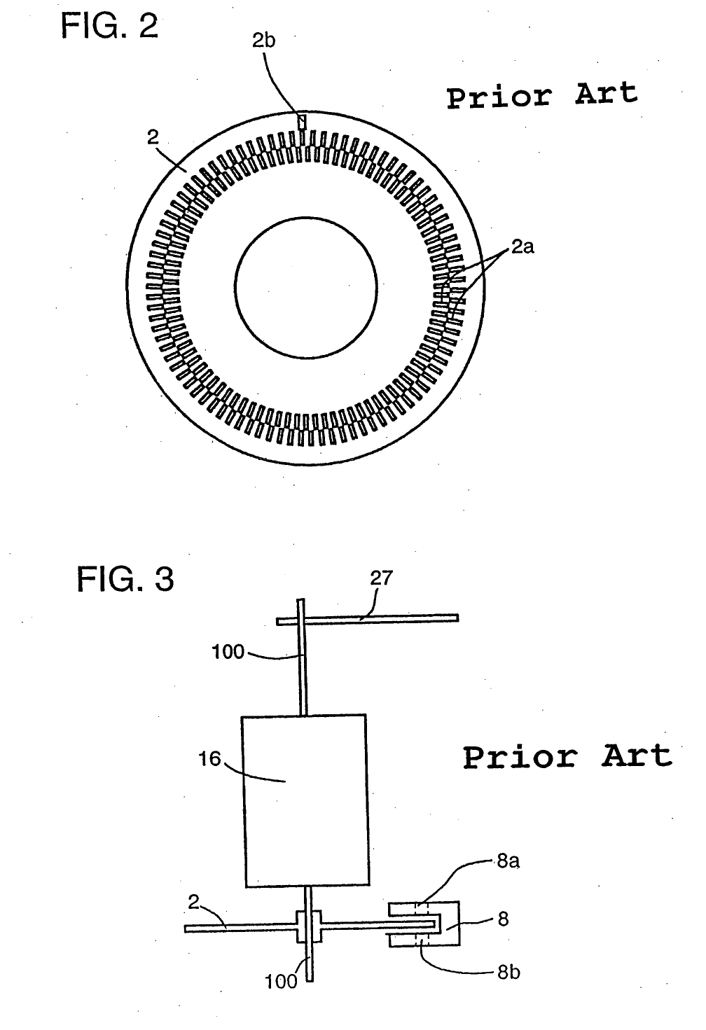

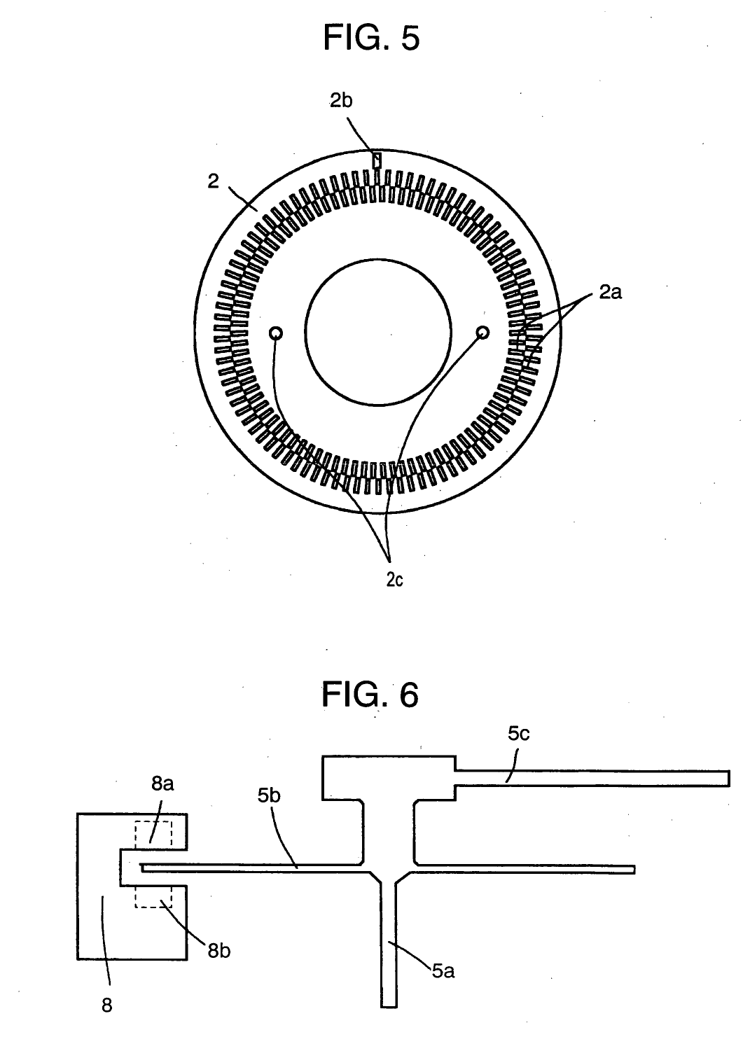

FIG. 1 is an outline sectional view showing a constitution of an electronic apparatus according to Embodiment 1 of the invention, particularly explaining, in details, the actuator 16, the moving member 60, the member to be read 2 and the detecting means 8 shown by block diagram at FIG. 4. Further, FIG. 5 is an outline top view of the member to be read 2 used in Embodiment 1. The actuator 16 is firmly fixed to an upper face of a support plate 52 by a screw. Further, the actuator 16 may be adhered or welded thereto so far as the actuator 16 can be fixed thereto firmly. Although various motors are utilized for the actuator 16, here, an explanation will be given of a case of using an ultrasonic motor.

In the ultrasonic motor 16, a vibrator 12 is fitted to a center shaft 14. A piezoelectric element 11 is adhered to a lower face of the vibrator 12. Meanwhile, a plurality of projections 13 are provided to an upper face of the vibrator 12. A rotor 51 is arranged on an upper side of the vibrator 12 to be brought into contact with the projections 13. A bearing is provided at center of the rotor 51 and the bearing is inserted with the center shaft 14. By constituting in this way, oscillation of the vibrator 12 is transmitted to the projections 13 and the rotor 51 is rotated with the center shaft 14 as center of rotation. An upper portion of the rotor 51 is pressed by a pressurizing spring 15 such that the rotor 51 is brought into contact with the projections 13 with constant pressing force. According to the ultrasonic motor 16, a drive signal is applied to the piezoelectric element 11 to thereby oscillate the vibrator 12, the oscillation is converted into rotational movement by friction between the projections 13 and the rotor 51 to thereby rotate the rotor 51. Further, there is used the principle of the ultrasonic motor 16 disclosed in, for example, Japanese Patent Laid-Open No. 170772/1995.

Two pieces of guide members 4 are fitted to the rotor 51 operating as the moving member 60 moved to rotate at locations of the upper face deviated from the center of rotation. The guide members 4 are rotated along with the rotor 51 and therefore, it is preferable to take an equal angular interval therebetween at equal distances from the center. There is provided a stepped difference portion lower than the central portion by one step at the upper face of the rotor 51. The member to be read 2 is arranged at the stepped difference portion. At this occasion, guide holes 2c are perforated such that the guide member 4 can be fitted to the member to be read 2. The member to be read 2 is perforated with slits 2a at equal intervals to constitute equal angles in view from the center of rotation as shown by, for example, FIG. 5. Further, the member to be read 2 is also perforated with a slit 2b of a reference position for indicating one turn. As shown by FIG. 1, for example, the guide holes 2c of the member to be read 2 are fitted to the guide member 4, further, the guide members 4 is fitted to a movable object member 6 fixed to the rotor 51 and rotating along with the rotor 51. As the movable object member 6, there is, for example, a mirror or the like. In the following, an explanation will mainly be given of a case of using a mirror. The mirror 6 is also provided with guide holes 6a similar to those of the member to be read 2 and the guide holes 6a of the mirror 6 are fitted to the guide members 4. At this occasion, the guide holes 2c and 6a are provided to the member to be read 2 and the mirror 6 such that the slit 2b constituting the reference of the member to be read 2 and the mirror 6 are brought into a predetermined positional relationship.

The detecting means 8 for detecting rotation is provided with a light emitting element 8a and a light receiving element 8b. The light emitting element 8a and the light receiving element 8b are provided to be opposed to each other to sandwich the member to be read 2 from above and from below. The guide members 4 determine positions in the radius direction and positions in the peripheral direction of the member to be read 2 and the mirror 6 relative to the rotor 51 to thereby prevent a shift in the positional relationship between the slit 2b constituting the reference of the member to be read 2 and the mirror 6 when the member to be read 2 and the mirror 6 are attached. Therefore, in an assembled state, operational accuracy of the mirror 6 is promoted and adjustment of positions of attaching the member to be read 2 and the mirror 6 is dispensed with. The guide members 4 are deviated from the center of rotation in order to reduce play angle produced by dimensional tolerance between the guide member 4 and the guide holes 2c and the 6a. Therefore, the operational accuracy of the mirror 6 can further be promoted.

Further, by using the ultrasonic motor 16 in the method of driving the above-described structure, there is realized the electronic apparatus having the ultrasonic motor operating the mirror 6 with high accuracy. By using the ultrasonic motor, there can be realized the electronic apparatus excellent in positional accuracy and response and saving power.

### Embodiment 2

An explanation will be given of Embodiment 2 in reference to FIG. 6. Embodiment 2 is characterized in that a rotating shaft 5a operating as a moving member, a member to be read 5b and an indicator 5c constituting a movable object member are integrally formed.

In FIG. 6, the rotating shaft 5a operating as a moving member is molded integrally with the indicator 5c constituting the movable object member and the member to be read 5b by injection molding of plastic. Although a lower portion of the rotating shaft 5a is omitted, the lower portion may be constructed by an actuator such as an ultrasonic motor for driving to rotate the rotating shaft 5a or a power transmission mechanism by gears for transmitting power of a drive source. As detecting means 8 for detecting rotation, the light emitting element 8a and the light receiving element 8b are provided to sandwich the member to be read 5b.

According to the above-described constitution, assembling of the member to be read 5b and the indicator 5c is dispensed with and a shift in a positional relationship of a slit constituting a reference of the member to be read 5b and the indicator 5c can be prevented. Therefore, adjustment of positions of attaching the member to be read 5b and the indicator 5c is dispensed with. Further, in this case, owing to the structure in which the member to be read 5b, the indicator 5c and the rotating shaft 5a are integrally formed, a total of the structure can be downsized, further, assembling steps can be saved.

### Embodiment 3

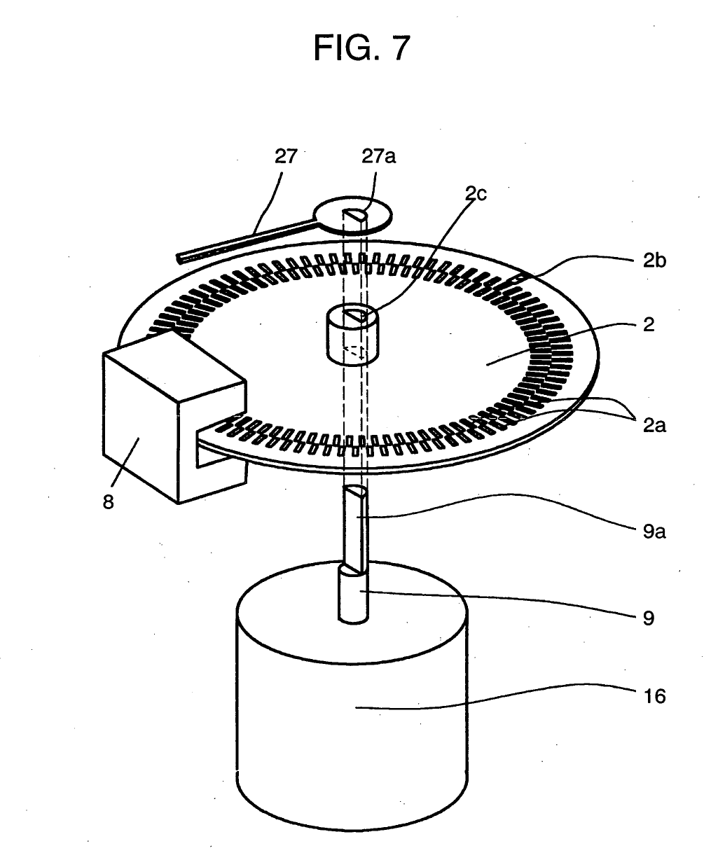

An explanation will be given of Embodiment 3 in reference to FIG. 7.

Embodiment 3 of FIG. 7 is constituted by the motor 16 constituting a drive source, a rotating shaft 9 of the motor constituting a moving member, the member to be read 2 attached to the rotating shaft 9, an indicator 27 constituting a movable object member attached to the rotating shaft 9, a guide member 9a formed integrally with the rotating shaft 9 and the detecting means 8 having the light emitting element 8a and the light receiving element 8b provided to sandwich the member to be read 2.

According to the rotating shaft 9, a motor side thereof is provided with a section in a circular shape and an end portion side thereof is provided with a section in a noncircular shape. The noncircular shape may be any shape so far as the shape is not a circular shape. Here, there is constituted a structure in which the shape is constituted by a semicircular shape, a portion of the rotating shaft 9 is worked by machining or the like, a portion of the semicircular shape operates as the guide member 9a and the guide member 9a is formed integrally with the rotating shaft 9. The member to be read 2 and the indicator 27 are provided with guide holes 2c and 27a having shapes similar to the noncircular shape. There is constituted a structure in which the guide member 9a is driven into the guide hole 2c of the member to be read 2 and the guide member 9a is driven into the guide hole 27a of the indicator 27.

According to Embodiment 3 having the above-described constitution, when both of the member to be read 2 and the indicator 27 are attached to the rotating shaft 9, the guide member 9a integral with the rotating shaft 9 constitutes a guide in the peripheral direction to thereby prevent a shift in a positional relationship between the slit 2b constituting the reference of the member to be read 2 and the indicator 27. Therefore, adjustment of positions of attaching the member to be read 2 and the indicator 27 is dispensed with and operational accuracy of the indicator 27 is promoted.

Further, according to Embodiment 3, it is not necessary to provide two pieces of the guide members as in Embodiment 1, the guide member 9a is integral with the rotating shaft 9 and therefore, a number of parts can be reduced.

### Embodiment 4

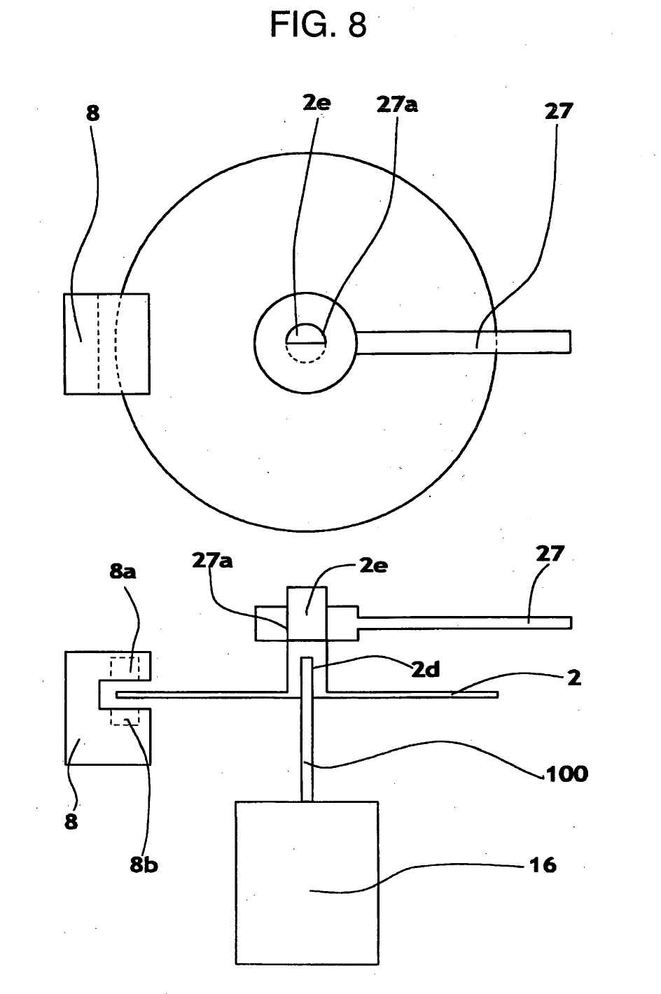

An explanation will be given of Embodiment 4 in reference to FIG. 8.

Embodiment of FIG. 8 is constituted by the motor 16 constituting a drive source, the rotating shaft 100 of the motor 16 constituting the moving member, the member to be read 2 attached to the rotating shaft 100, the indicator 27 constituting the movable object member attached to the member to be read 2, a guide member 2e formed integrally with the member to be read 2 and the light emitting element 8a and the light receiving element 8b provided to sandwich the member to be read 2.

The member to be read 2 is provided with a recess portion 2d at a rotational center portion on a lower face side thereof and the rotating shaft 100 is fitted to the recess portion 2d of the member to be read 2. The guide member 2e is integrally formed with the rotational center portion on an upper face side of the member to be read 2. The guide member 2e is provided with a section in a noncircular shape, which is a semicircular shape in this case. The indicator 27 is provided with a guide hole 27a having a shape similar to that of the section in the noncircular shape. The indicator 27 is fixed by fitting the guide hole 27a to the guide member 2e.

According to Embodiment 4 having the above-described constitution, when the member to be read 2 and the indicator 27 are attached to the rotating shaft 100, the guide member 2e integral with the member to be read 2, constitutes a guide in the peripheral direction to thereby prevent a shift in a positional relationship between a slit constituting the reference of the member to be read 2 and the indicator 27. Therefore, adjustment of positions of attaching the member to be read 2 and the indicator 27 is dispensed with and operational accuracy of the indicator 27 is promoted.

### Embodiment 5

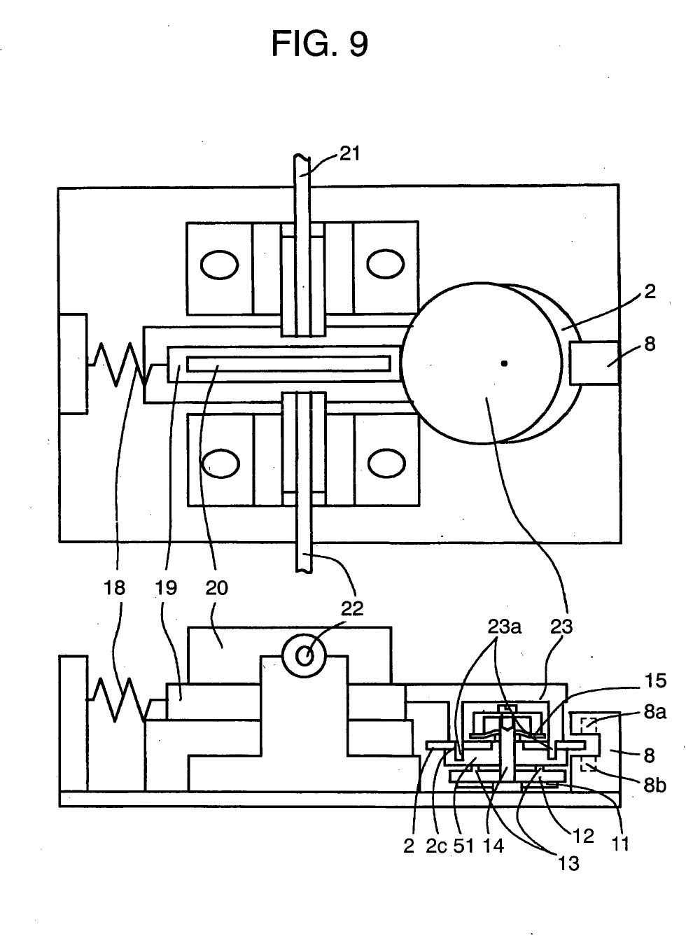

FIG. 9 shows an optical filter with an ultrasonic motor as a drive source.

The ultrasonic motor is constituted by the vibrator 12 constituted by adhering the piezoelectric element 11 to a lower face of an elastic member, the projections 13 provided at the upper face of the vibrator 12, the rotor 51 arranged to be brought into contact with the projection 13, the center shaft 14 fixed with the vibrator 12 for enabling to rotate the rotor 51 and the pressurizing spring 15 for pressing the rotor 51. According to the ultrasonic motor, a drive signal is applied to the piezoelectric element 11 to thereby oscillate the vibrator 12, the oscillation is converted into rotational movement by friction between the projections 13 and the rotor 51 to thereby rotate the rotor 51. In this case, the rotor 51 operates as the moving member.

In this case, the movable object member is constituted by an eccentric cam 23 and guide members 23a are integrally formed therewith at locations deviated from the center of rotation of the eccentric cam 23. The guide members 23a penetrate the guide holes 2c of the member to be read 2 and are driven into the rotor 51. An urge spring 18 is connected to one end face of a straight moving base 19 and urges the straight moving base 19 to a side of the eccentric cam 23 in contact with other end face of the straight moving base 19. The straight moving base 19 is provided with a multilayered film filter 20. An input port 21 of an optical fiber and an output port 22 of an optical fiber are arranged to sandwich the multilayered film filter 20.

Further, there is provided the detecting means 8 having the light emitting element 8a and the light receiving element 8b provided to be opposed to each other to sandwich the member to be read 2.

In FIG. 9, when the eccentric cam 23 is rotated in one direction by the ultrasonic motor, the straight moving base 19 is moved to the right side by the urge force of the urge spring 18, thereafter, when the ultrasonic motor is rotated in other direction, the eccentric cam 23 is also rotated in the other direction and the straight moving base 19 is pressed by the eccentric cam 23 and is moved to the left side by overcoming the urge force of the urge spring 18. Thereby, the multilayered film filter 20 is moved in the left and right direction to thereby control states of wavelength, intensity, presence or absence or the like of light outputted from the input port 21 of the optical fiber and transmitted through the multilayered film filter 20.

In this case, the guide members 23a are integrally formed with the eccentric cam and therefore, a number of parts can be reduced and the guide members 23a prevent a shift in a positional relationship between the member to be read 2 and the eccentric cam 23. Therefore, adjustment of positions of attaching the member to be read 2 and the eccentric cam 23 is dispensed with and the operational accuracy of the eccentric cam 23 and also operational accuracy of the multilayered film filter 20 are promoted.

### Embodiment 6

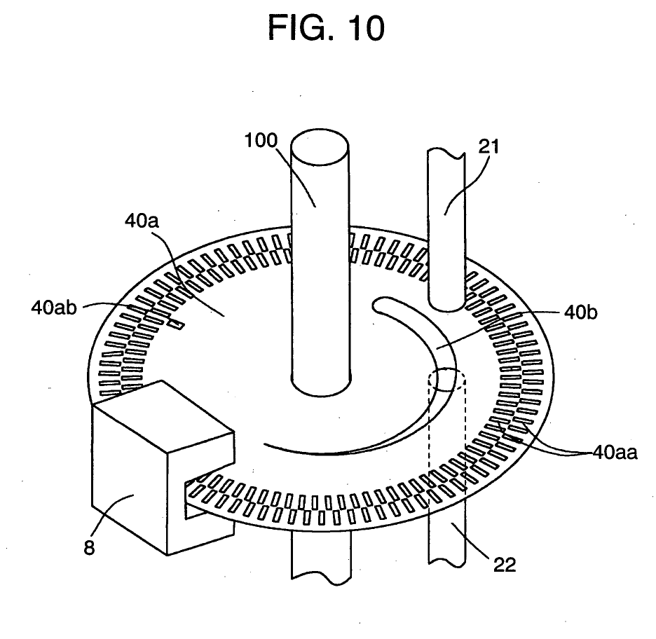

An explanation will be given of Embodiment 6 in reference to FIG. 10. FIG. 10 shows a constitution of a variable attenuator for adjusting an optical amount of light, which is constituted by the rotating shaft 100 rotated by drive force of the actuator 16 and constituting a moving member, a member to be read 40a fitted to the rotating shaft 100, slits 40aa at equal intervals as well as a slit 40ab constituting a reference formed by an etching process, an optical amount adjusting slit 40b constituting a movable object member formed integrally with the member to be read 40a by the etching process, an optical fiber input port 21 and an optical fiber output port 22 provided to sandwich the optical amount adjusting slit 40b and the detecting means 8 having the light emitting element 8a and the light receiving element 8b provided to sandwich the member to be read 2.

The optical amount adjusting slit 40b is provided on a circle concentric with the center of rotation and, in this case, formed in a shape in which a width in the radius direction is slenderized toward one side in the peripheral direction. An optical signal outputted from the optical fiber input port 21 is inputted to the optical fiber output port 22 via the optical amount adjusting slit 40b.

When the rotating shaft 100 is driven by the actuator 16, the member to be read 40a and the optical amount adjusting slit 40b are also rotated. The width of the optical slit 40b between the optical fibers differ depending on the position of the optical amount adjusting slit 40b. Therefore, the optical amount of the optical signal transmitting through the optical amount adjusting slit 40b can be changed by the rotational angle. The position of the rotating shaft 100 is detected by the detecting means 8 having the light emitting element 8a and the light receiving element 8b provided to be opposed to each other to sandwich the member to be read 40a. There is constituted a variable attenuator for adjusting the optical amount by controlling the position.

The member to be read 40a and the optical amount adjusting slit 40b are integrally formed and therefore, a shift in a positional relationship between the slit 40a b constituting the reference of the member to be read 40a and the optical amount adjusting slit 40b can be prevented. Therefore, adjustment of positions of attaching the member to be read 40a and the optical amount adjusting slit 40b is dispensed with and the optical amount adjusting accuracy is promoted.

Although in this case, the optical amount adjusting slit 40b is provided continuously in the peripheral direction, for example, a plurality of circular slits having different diameters may continuously be provided in the peripheral direction.

### Embodiment 7

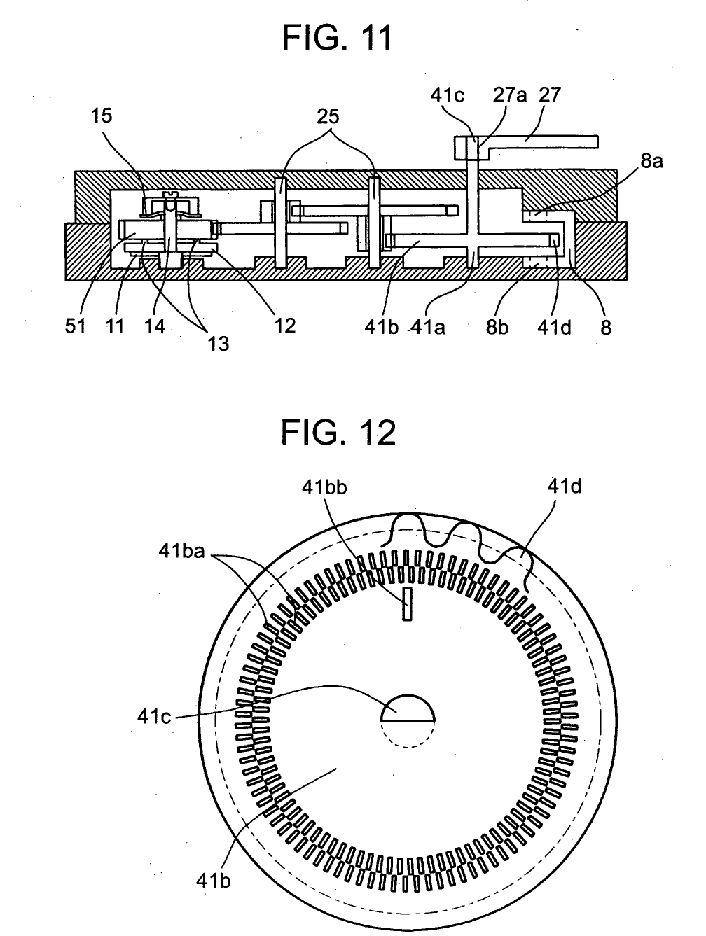

An explanation will be given of Embodiment 7 in reference to FIG. 11 and FIG. 12.

FIG. 11 is an outline sectional view for explaining a constitution in which drive force of the ultrasonic motor is transmitted to a rotating shaft 41a constituting a movable member via a transmission mechanism 25 to thereby move the indicator 27 constituting the movable object member moved in cooperation with the rotating shaft 41a.

The ultrasonic motor is constituted by the vibrator 12 constituted by adhering the piezoelectric element 11 to a lower face of an elastic member, the projections 13 provided at an upper face of the vibrator 12, the rotor 51 arranged to be brought into contact with the projections 13, the center shaft 14 fixed to the vibrator 12 for enabling to rotate the rotor 51 and the pressurizing spring 15 for pressing the rotor 51. According to the ultrasonic motor, the vibrator 12 is oscillated by applying a drive signal to the piezoelectric element 11 and the oscillation is converted into rotational movement by friction between the projections 13 and the rotor 51 to thereby rotate the rotor 51.

In this case, the rotational force of the rotor 51 rotates the rotating shaft 41a via the power transmission mechanism 25 such as gears. The rotating shaft 41a is attached with the indicator 27 constituting the movable object member. A portion of the rotating shaft 41a attached with the indicator 27, operates as a guide member 41c in a noncircular sectional shape similar to that of the rotating shaft shown in Embodiment 3 and is fitted with the indicator 27 having the guide hole 27a having a similar shape. Further, a gear 41d for directly transmitting rotational force of the power transmission mechanism 25 to the rotating shaft 41a, is integrally formed with the rotating shaft 41a. Rotation is detected by the light emitting element 8a, the light receiving element 8b and a member to be read 41b integrally formed with the gear 41d for directly transmitting the rotational force of the power transmission mechanism 25 to the rotating shaft 45a.

FIG. 12 is an outline top view of the member to be read 41b integrally formed with the gear 41d for directly transmitting the rotational force of the power transmission mechanism 25 to the rotating shaft 45a and the rotating shaft 41a. An outer periphery of a circular disk is inscribed with teeth and on its inner side, there are provided slits 41ba at equal intervals for providing rotational angle information and a slit 41bb constituting a reference for providing an absolute position. The rotating shaft 41a is integrally formed with the center of rotation of the member to be read 41b and the guide member 41c is integrally formed with the rotating shaft 41a.

The gear 41d for directly transmitting the rotational force of the power transmission mechanism 25 to the rotating shaft 41a, the member to be read 41b, the rotating shaft 41a and the guide member 41c are integrally formed and therefore, small-sized formation can be achieved and a reduction in cost can be achieved by reducing assembling steps. Further, the guide member 41c formed integrally with the rotating shaft 41a prevents a shift in a positional relationship between the indicator 27 and the slit 41bb constituting the reference of the member to be read 41b. Therefore, promotion of operational accuracy of the indicator 27 can be achieved and adjustment of positions of attaching the slit 41bb constituting the reference of the member to be read 41b and the indicator 27 is dispensed with.

Further, the kind of the encoder is not limited to the above-described incremental type but may be the absolute type and the principle is not limited to the optical type.

As described above, according to the invention, by fixing the member to be read by the guide members, the shift in the positional relationship between the slit constituting the reference of the member to be read and the movable object member can be eliminated. Thereby, the operational accuracy of the movable object member is promoted, further, the step for adjusting the shift in the positional relationship between the slit constituting the reference of the member to be read and the movable object member, is dispensed with and mass production performance can be promoted. Further, also with regard to the positional relationship between the slit constituting the reference of the member to be read and the movable object member, the dispersion can be reduced.

1-6. (canceled).

7. An electronic apparatus comprising: a motor; a disc-shaped readable member rotationally driven by the motor and having at least one first slit therein and an optical amount adjusting slit having an arcuate shape with a radius of curvature identical to that of a rotational path of the readable member, and having a width that tapers along the arcuate shape thereof; and a detecting device for detecting rotation of the readable member and having a light emitting element and a light receiving element sandwiching the readable member so that light is projected through the at least one first slit once for each revolution of the readable member.

8. An electronic apparatus according to claim 7; wherein the motor comprises an ultrasonic motor.

9. An electronic apparatus according to claim 7; wherein the at least one first slit comprises a plurality of first slits; and wherein the light emitting element is disposed on one side of the slits for emitting light through the respective slits, and the light receiving element is disposed on an opposite side of the slits for receiving light passing through the slits and outputting a corresponding signal.

10. An electronic apparatus according to claim 7; further comprising a control circuit for controlling rotational movement of the readable member in accordance with an output signal of the light receiving element.

11. An electronic apparatus according to claim 7; wherein the motor is an ultrasonic motor comprising a vibrator having a piezoelectric element thereon for producing ultrasonic vibrations in the vibrator, and a plurality of projections extending from the vibrator; and wherein the readable member is disposed on the projections to undergo movement in response to the ultrasonic vibrations.

12. An electronic apparatus according to claim 7; wherein the electronic apparatus is a variable attenuator.

13. An electronic apparatus comprising: a motor; a readable member rotationally driven by the motor and having at least one first slit therein and an optical amount adjusting slit having an arcuate shape with a radius of curvature identical to that of a rotational path of the readable member; and a detecting device for detecting rotation of the readable member.

14. An electronic apparatus according to claim 13; wherein the motor comprises an ultrasonic motor.

15. An electronic apparatus according to claim 13; wherein the at least one first slit comprises a plurality of first slits; and wherein the detecting device comprises a light emitting element disposed on one side of the slits so that light is projected through a respective one of the slits once for each revolution of the readable member, and a light receiving element disposed on an opposite side of the slits for receiving light passing through the slits and outputting a corresponding signal.

16. An electronic apparatus according to claim 15; further comprising a control circuit for controlling rotational movement of the readable member in accordance with an output signal of the light receiving element.

17. An electronic apparatus according to claim 13; wherein the motor is an ultrasonic motor comprising a vibrator having a piezoelectric element thereon for producing ultrasonic vibrations in the vibrator, and a plurality of projections extending from the vibrator; and wherein the readable member is disposed on the projections to undergo movement in response to the ultrasonic vibrations.

18. An electronic apparatus according to claim 13; wherein the electronic apparatus is a variable attenuator.
